(19) United States
(12) Patent Application Publication
(10) Pub. No.: US 2026/0182286 A1
(43) Pub. Date: Jun. 25, 2026

(54) PREPARATION PROCESS OF MULTI-HEIGHT WAVEGUIDE

(71) Applicant: SILITH TECHNOLOGY PTE. LTD., SINGAPORE (SG)

(72) Inventors: Nanfei ZHU, Shanghai (CN); Ke ZHANG, Shanghai (CN); Yunchu YU, Shanghai (CN)

(73) Assignee: SILITH TECHNOLOGY PTE. LTD., SINGAPORE (SG)

(21) Appl. No.: 19/537,443

(22) Filed: Feb. 11, 2026

Related U.S. Application Data
(63) Continuation of application No. PCT/CN2024/112067, filed on Aug. 14, 2024.

(30) Foreign Application Priority Data
Aug. 16, 2023 (CN) 202311030422.9

(51) Int. Cl. H10P 50/00; G02B 6/12; G02B 6/13; G02B 6/136

(52) U.S. Cl. CPC H10P 50/73; G02B 6/12; G02B 6/12002; G02B 6/12004; G02B 6/12007; G02B 6/13; G02B 6/136

(57) ABSTRACT

A preparation process of a multi-height waveguide is provided, which comprises the following steps of: providing a substrate, forming a first coating layer on one surface of the substrate, and forming a first waveguide layer on the surface, far away from the substrate, of the first coating layer; performing photoetching and etching on the first waveguide layer for the first time to complete full-height region patterning of the multi-height waveguide; performing photoetching and etching on the first waveguide layer for the second time to complete the patterning of the shallow etching area of the multi-height waveguide; performing photoetching and etching on the first waveguide layer for the third time to complete deep area patterning of the multi-height waveguide; the etching step is carried out step by step in a hard mask self-alignment mode.

### CROSS-REFERENCES TO RELATED APPLICATIONS

This application is a continuation of international application of PCT application serial no. PCT/CN2024/112067, filed on Aug. 14, 2024, which claims the priority benefit of China application serial no. 202311030422.9, filed on Aug. 16, 2023. The entirety of each of the above-mentioned patent application is hereby incorporated by reference herein and made a part of this specification.

### TECHNICAL FIELD

The present disclosure relates to the technical field of chip preparation, in particular to a preparation process of a multi-height waveguide.

### BACKGROUND

Following rapid development of information industry and arrival of Internet of Things, cloud computing and big data era, a requirement on capacity and processing speed of information data is higher and higher. Following development of Moore's law, a traditional microelectronic device has a size gradually reduced, but a performance and a power consumption continuously improved, however, under a huge requirement of data application, a disadvantage in a plurality of aspects including rate, power consumption and more, is increasingly prominent, while an photonic integrated circuit (PIC) has an obvious advantage in a plurality of aspects including size, power consumption, cost, reliability and more, thus has becoming a mainstream in future.

A waveguide and a plurality of various optical devices, acting as a carrier for loading, transmitting and converting a signal, is one of a plurality of key technologies in a photonic integrated chip. A plurality of different performance requirements require a plurality of different shapes of the waveguide and the plurality of optical devices, resulting in a need for different material thickness of an optical waveguide.

In the prior art, there are two methods to process an optical waveguide material having a multi-height. One is a step-by-step etching process, having a certain amount being etched in each step, until accumulating to a full etching. However, a large problem of this method is that an overlay error between different steps will form an unstable step height, especially between several steps during a partial etch phase (PEP), having an effect on performance stability. Another is keeping different etching process totally independent, a problem of this method is that a layout processing will be very troublesome, an overlapping relationship between different etching steps shall be considered comprehensively, increasing a complexity when processing a layout, instead of facilitating a layout design.

### SUMMARY

In order to solve at least one technical problem in the prior art, the present disclosure provides a preparation process of a multi-height waveguide.

In order to achieve the purpose stated above, the present disclosure adopts a technical solution: a preparation process of a multi-height waveguide, wherein the multi-height waveguide comprises a full-height region, a shallow-etched region and a deep-etched region, a height of the full-height region from a substrate is greater than a height of the shallow-etched region from the substrate, and the height of the shallow-etched region from the substrate is greater than a height of the deep-etched region from the substrate, comprising following steps:
step 1: providing a substrate, forming a first coating layer on a surface of the substrate, and forming a first waveguide layer on a surface of the first coating layer away from the substrate;
step 2: performing a first photoetching and etching process on the first waveguide layer to complete patterning the full-height region of the multi-height waveguide;
step 3: performing a second photoetching and etching process on the first waveguide layer to complete patterning the shallow-etched region of the multi-height waveguide;
step 4: performing a third photoetching and etching process on the first waveguide layer to complete patterning the deep-etched region of the multi-height waveguide;
the etching is adopting a hard mask self-alignment manner to etch step by step.

Further, performing the first photoetching and etching process on the first waveguide layer to complete patterning the full-height region of the multi-height waveguide, comprising:
performing a deposition on a surface of the first waveguide layer away from the substrate and forming a first hard mask layer;
adopting the photoetching and etching process to pattern the first waveguide layer, and forming the full-height region of the multi-height waveguide, while retaining the first hard mask layer on the full-height region.

Further, the first hard mask layer is formed by a thin film deposition;
the thin film is chosen from aluminum nitride, aluminum oxynitride, aluminum oxide, polysilicon, silicon nitride, silicon oxynitride, silicon dioxide, SiCN, or SiOCH.

Further, performing the second photoetching and etching process on the first waveguide layer to complete patterning the shallow-etched region of the multi-height waveguide, comprising:
removing a photoresist residue on the surface of the first waveguide layer, and forming a first organic dielectric layer on the surface of the first waveguide layer away from the substrate, while covering the full-height region;
performing a deposition on a surface of the first organic dielectric layer away from the substrate and forming a second hard mask layer;
adopting the photoetching and etching process to pattern the first waveguide layer, and forming the shallow-etched region of the multi-height waveguide, while retaining the second hard mask layer on the shallow-etched region.

Further, the second hard mask layer is formed by a thin film deposition;
the thin film is chosen from aluminum nitride, aluminum oxynitride, aluminum oxide, polysilicon, silicon nitride, silicon oxynitride, silicon dioxide, SiCN, or SiOCH.

Further, during a second etching process, the second hard mask layer is etched first, then the first organic dielectric layer is etched, and finally the first waveguide layer is etched.

Further, the first organic dielectric layer is formed by coating an organic dielectric layer with a preset thickness on a surface of the full-height region and the first waveguide layer;
the first organic dielectric layer is chosen from Amorphous Carbon, BARC, CHM701B, HM8006, HM8014, ODL-102, or a plurality of other commercial adhesives.

Further, performing the third photoetching and etching process on the first waveguide layer to complete patterning the deep-etched region of the multi-height waveguide, comprising:
forming a second organic dielectric layer on the surface of the first waveguide layer away from the substrate, while covering the full-height region and the shallow-etched region;
performing a deposition on a surface of the second organic dielectric layer and forming a third hard mask layer;
patterning the first waveguide layer by a process of photoetching and etching, to form the deep-etched region of the multi-height waveguide;
removing the photoresist residue.

Further, the third hard mask layer is formed by a thin film deposition;
the thin film is chosen from aluminum nitride, aluminum oxynitride, aluminum oxide, polysilicon, silicon nitride, silicon oxynitride, silicon dioxide, SiCN, or SiOCH.

Further, during a third etching process, the third hard mask layer is etched first, then the second organic dielectric layer is etched, and finally the first waveguide layer is etched.

Further, the etching may be a dry etch or a wet etch.

By adopting the technical solution stated above, compared with the prior art, the present disclosure has a plurality of following advantages:
the present disclosure performs a gradual etching process by adopting a hard mask self-alignment manner, before forming a multi-height waveguide device without a step, a pattern at each height, due to the self-alignment, will not cause an unstable step height due to the overlay error, an overlapping part at different heights is determined by a pattern of a thickest layer, a corresponding area between a layout and a process is clear, it is convenient for a designer to adopt an automatic script to draw automatically, and meanwhile, it improves a performance and a design intuition of a device.

### BRIEF DESCRIPTION OF THE DRAWINGS

FIG. 1 illustrates a schematic structural diagram on a multi-height waveguide according to Embodiment I of the present disclosure;

FIG. 2 illustrates a schematic outline diagram on a multi-height waveguide in step 1 of a preparation process of a multi-height waveguide according to Embodiment I of the present disclosure;

FIG. 3 illustrates a schematic outline diagram I on a multi-height waveguide in step 2 of a preparation process of a multi-height waveguide according to Embodiment I of the present disclosure;

FIG. 4 illustrates a schematic outline diagram II on a multi-height waveguide in step 2 of a preparation process of a multi-height waveguide according to Embodiment I of the present disclosure;

FIG. 5 illustrates a schematic outline diagram I on a multi-height waveguide in step 3 of a preparation process of a multi-height waveguide according to Embodiment I of the present disclosure;

FIG. 6 illustrates a schematic outline diagram II on a multi-height waveguide in step 3 of a preparation process of a multi-height waveguide according to Embodiment I of the present disclosure;

FIG. 7 illustrates a schematic outline diagram I on a multi-height waveguide in step 4 of a preparation process of a multi-height waveguide according to Embodiment I of the present disclosure;

FIG. 8 illustrates a schematic outline diagram II on a multi-height waveguide in step 4 of a preparation process of a multi-height waveguide according to Embodiment I of the present disclosure;

FIG. 9 illustrates a schematic structural diagram on a multi-height waveguide manufactured by a preparation process of a multi-height waveguide according to Embodiment I of the present disclosure.

### DESCRIPTION OF THE EMBODIMENTS

To make the objective, technical solutions and advantages of the present disclosure clearer, the technical solutions in the embodiments of the present disclosure will be clearly and completely described below with reference to the accompanying drawings of the present disclosure. Apparently, the drawings are all simplified schematic diagrams and merely illustrating the basic structure of the present disclosure in a schematic manner, thus only compositions related to the present disclosure are shown, and it is noted that, in a case of no conflict, the embodiments in the present disclosure and the features in the embodiments may be combined with each other.

A plurality of specific details are set forth in the following description in order to fully understand the present disclosure, however, the present disclosure may also be implemented in a plurality of other manners different from those described herein, and therefore, the protection scope of the present disclosure is not limited by the specific embodiments disclosed below.

### Embodiment I

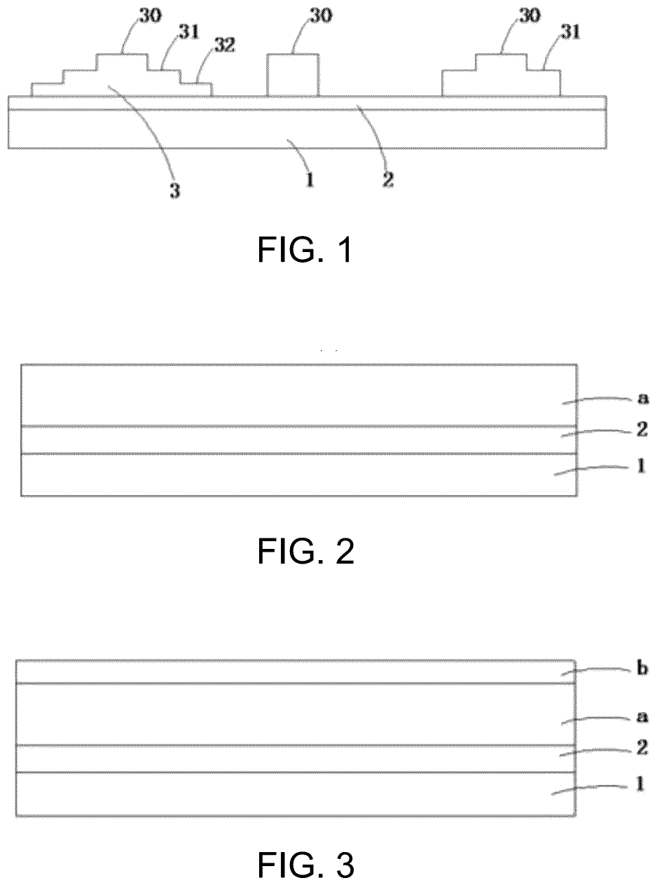

Referencing to FIG. 1, a multi-height waveguide comprises a substrate 1, a coating layer 2 formed on a surface of the substrate 1, and a first waveguide 3 formed on a surface of the coating layer 2 away from the substrate 1. The first waveguide 3 comprises a full-height region 30, a shallow-etched region 31 and a deep-etched region 32, wherein a height of the full-height region 30 from the substrate 1 is greater than a height of the shallow-etched region 31 from the substrate 1, and the height of the shallow-etched region 31 from the substrate 1 is greater than a height of the deep-etched region 32 from the substrate 1.

The present disclosure provides a preparation process of a multi-height waveguide, so as to form the multi-height waveguide stated above, the preparation process of the multi-height waveguide comprises a plurality of following steps:
step 1: providing a substrate 1, forming a first coating layer 2 on a surface of the substrate 1, and forming a first waveguide layer A on a surface of the first coating layer 2 away from the substrate 1;
step 2: performing a first photoetching and etching process on the first waveguide layer A to complete patterning the full-height region of the multi-height waveguide, shown as FIG. 2;
step 3: performing a second photoetching and etching process on the first waveguide layer A to complete patterning the shallow-etched region of the multi-height waveguide;
step 4: performing a third photoetching and etching process on the first waveguide layer A to complete patterning the deep-etched region of the multi-height waveguide;
the etching is adopting a hard mask self-alignment manner to etch step by step.

Since the hard mask self-alignment manner is adopted to perform a gradual etching, a problem of overlay error will not appear, thus a step height unstable will not be induced due to the overlay error. An overlapping part between different heights is determined by a pattern of a thickest layer, a corresponding area between a layout and a process is clear, thus it is convenient for a designer to adopt an automatic script to draw automatically, and meanwhile, it improves a performance and a design intuition of a device.

Further, the substrate 1 may be a light/electromagnetic wave waveguide chip substrate made of a plurality of materials including silicon, lithium niobate or a compound in groups III-V.

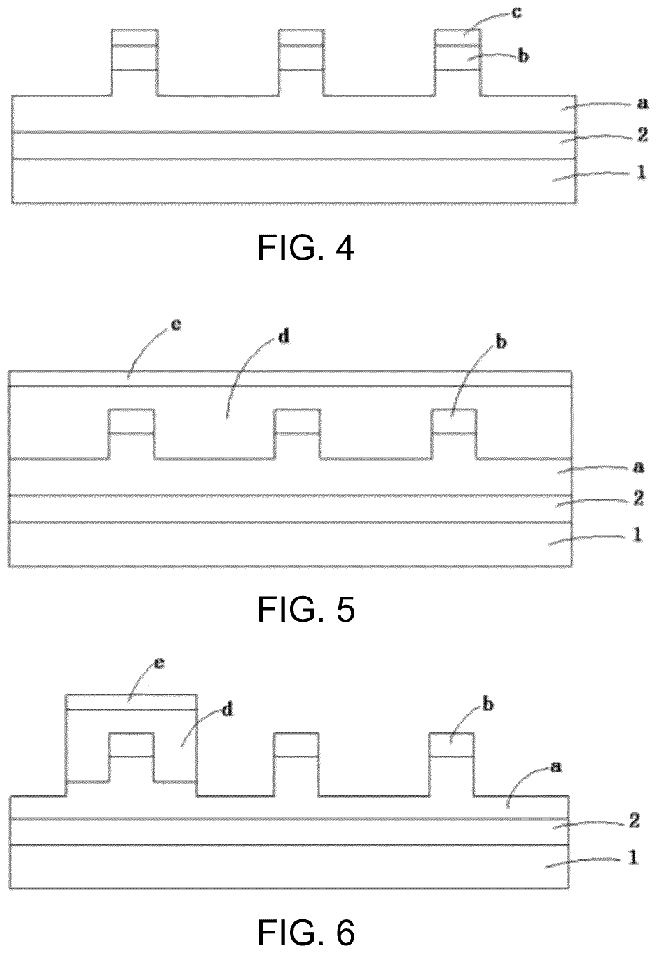

Further, referencing to FIG. 3 and FIG. 4, performing the first photoetching and etching process on the first waveguide layer A to complete patterning the full-height region of the multi-height waveguide, comprises:
performing a deposition on a surface of the first waveguide layer A away from the substrate 1 and forming a first hard mask layer B;
adopting a process of the photoetching and etching to pattern the first waveguide layer A, and forming the full-height region 30 of the multi-height waveguide, while retaining the first hard mask layer B on top of the full-height region 30.

Wherein a depth H1 of the first etching is a depth required by the shallow-etched region 31, that is, the depth H1 of the first etching is a height difference from a top of the full-height region 30 to a top of the shallow-etched region 31.

Further, the first hard mask layer B is formed by a thin film deposition, while the first hard mask layer B and the first waveguide layer have a relatively high etching selectivity ratio.

Preferably, the thin film is chosen from aluminum nitride, aluminum oxynitride, aluminum oxide, polysilicon, silicon nitride, silicon oxynitride, silicon dioxide, SiCN, or SiOCH.

Further, the deposition may be performed by adopting one of a plurality of processes including LPCVD, PECVD, ALD or PVD.

Further, referencing to FIG. 5 and FIG. 6, performing the second photoetching and etching process on the first waveguide layer A to complete patterning the shallow-etched region 31 of the multi-height waveguide, comprising:
removing a residue of photoresist C on the surface of the first waveguide layer A, and forming a first organic dielectric layer D on the surface of the first waveguide layer A away from the substrate 1, while covering the full-height region 30;
performing a deposition on a surface of the first organic dielectric layer D away from the substrate 1 and forming a second hard mask layer E;
adopting a process of photoetching and etching to pattern the first waveguide layer A, and forming the shallow-etched region 31 of the multi-height waveguide, while retaining the second hard mask layer E on the shallow-etched region 31.

Further, the second hard mask layer E is formed by a thin film deposition. Preferably, the second hard mask layer E is formed by depositing aluminum nitride, aluminum oxynitride, aluminum oxide, polysilicon, silicon nitride, silicon oxynitride, silicon dioxide, SiCN, or SiOCH.

Further, during a process of the second etching, the second hard mask layer E is etched first, then the first organic dielectric layer D is etched, and finally the first waveguide layer A is etched.

The full-height region 30 is located in a photolithography open area. After the first organic dielectric layer D is etched through, the first hard mask layer B on a top of the full-height region 30 is exposing. During a process of the first waveguide layer A being continuously etched, the full-height region 30 is protected from being etched by the first hard mask layer B acting as a hard mask, and the shallow-etched region 31 is protected from being etched by the photoresist and the second hard mask layer E, while a remaining region of the first waveguide layer A continues to be etched downward, until an etching depth H2 is accumulated to reach a depth required by the deep-etched region 32 before getting to a stop.

Further, the first organic dielectric layer D is formed by coating an organic dielectric in a preset thickness on a surface of the full-height region 30 and the surface of the first waveguide layer A;

The organic dielectric may be selected from amorphous carbon, BARC, CHM701B, HM8006, HM8014, ODL-102, or a plurality of other commercial adhesives

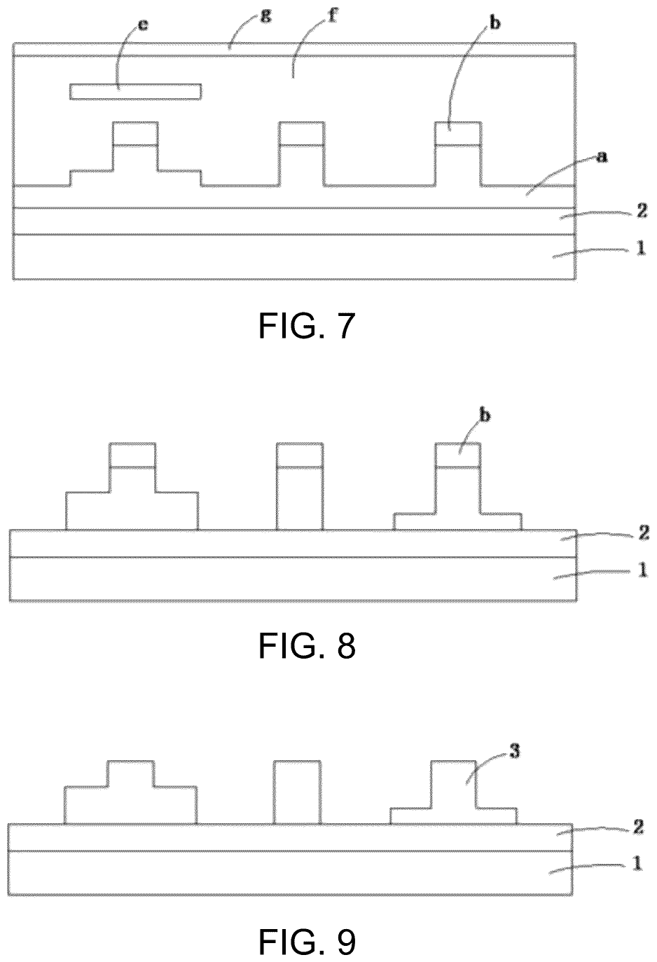

Further, referencing to FIG. 7 and FIG. 8, performing the third photoetching and etching process on the first waveguide layer A to complete patterning the deep-etched region 32 of the multi-height waveguide, comprising:
forming a second organic dielectric layer F on the surface of the first waveguide layer A away from the substrate 1, while covering the full-height region 30 and the shallow-etched region 31;
performing a deposition on a surface of the second organic dielectric layer F and forming a third hard mask layer G;
patterning the first waveguide layer A by a process of photoetching and etching, before forming the deep-etched region 32 of the multi-height waveguide;
removing a residue of the first hard mask layer B, and obtaining a final product of the multi-height waveguide shown as FIG. 9, according to the preparation process of Embodiment I.

Further, the third hard mask layer G is formed by a thin film deposition. Preferably, the third hard mask layer G is formed by depositing aluminum nitride, aluminum oxynitride, aluminum oxide, polysilicon, silicon nitride, silicon oxynitride, silicon dioxide, SiCN, or SiOCH.

Further, during the process of etching, the third hard mask layer G is etched first, then the second organic dielectric layer F is etched, and finally the first waveguide layer A is etched.

The full-height region 30 and the shallow-etched region 31 are located in a photolithography open area. After finishing etching the second organic dielectric layer F, the first hard mask layer B on top of the full-height region 30 and the second hard mask layer E on the shallow-etched region 31 are exposing. During a process of continuing etching the first waveguide layer A by a waveguide layer etching, the full-height region 30 is protected from being etched by the first hard mask layer B acting as a hard mask, the shallow-etched region 31 is protected from being etched by the second hard mask layer E, and the deep-etched region 32 is protected from being etched by the photoresist and the third hard mask layer G, while a remaining region of the first waveguide layer A resumes to be etched downward, until the first waveguide layer A is totally etched off. After finishing the third etching, the second hard mask layer E and the third hard mask layer G are totally consumed, and residual of the first organic dielectric layer D and the second organic dielectric layer F can be removed by ashing or degumming.

Further, a residual of the first hard mask B may be removed by etching in a high etching selectivity ratio, or may be temporarily reserved then being removed until a subsequent CMP process for a coating layer being stopped.

Further, the etching may be a dry etching or a wet etching.

It is noted that the preparation process of the multi-height waveguide of the present disclosure is not limited to preparing a three-height waveguide stated in the embodiments above, but being able to be expanded to more height and levels according to an application requirement.

In the description of the present disclosure, it should be noted that the terms “arranged”, “mounted” and “connected” should be understood in a broad sense unless being specified and limited definitely otherwise, for example, it may be a fixed connection, a detachable connection, or an integral connection; it may be a mechanical connection or an electrical connection; it may be directly connected or indirectly connected by using an intermediate medium; and it may be a communication inside two elements. For those of ordinary skill in the art, the specific meanings of the above terms in the present disclosure can be understood through a specific situation.

The above description of the embodiments disclosed enables those skilled in the art to implement or use the present disclosure. Various modifications to the above embodiments shall be apparent to those skilled in the art, and the general principles defined herein may be implemented in other embodiments without departing from the spirit or scope of the present disclosure. Thus, the present disclosure will not be limited to the embodiments described herein, but be in a widest scope consistent with the principles and novel features disclosed herein.

What is claimed is:

1. A preparation process of a multi-height waveguide, wherein the multi-height waveguide comprises a full-height region, a shallow-etched region and a deep-etched region, a height of the full-height region from a substrate is greater than a height of the shallow-etched region from the substrate, and the height of the shallow-etched region from the substrate is greater than a height of the deep-etched region from the substrate, and
the preparation process comprises the following steps:
step 1: providing the substrate, forming a first coating layer on a surface of the substrate, and forming a first waveguide layer on a surface of the first coating layer away from the substrate;
step 2: performing a first photoetching and etching process on the first waveguide layer to complete patterning the full-height region of the multi-height waveguide, comprising:
performing a deposition on a surface of the first waveguide layer away from the substrate and forming a first hard mask layer; and
adopting the first photoetching and etching process to pattern the first waveguide layer, and forming the full-height region of the multi-height waveguide, while retaining the first hard mask layer on the full-height region,
wherein a depth of the first etching is a depth required by the shallow-etched region, or the depth of the first etching is a height difference from a top of the full-height region to a top of the shallow-etched region;
step 3: performing a second photoetching and etching process on the first waveguide layer to complete patterning the shallow-etched region of the multi-height waveguide, comprising:
removing a photoresist residue on the surface of the first waveguide layer, and forming a first organic dielectric layer on the surface of the first waveguide layer away from the substrate, while covering the full-height region;
performing a deposition on a surface of the first organic dielectric layer away from the substrate and forming a second hard mask layer; and
adopting the second photoetching and etching process to pattern the first waveguide layer, and forming the shallow-etched region of the multi-height waveguide, while retaining the second hard mask layer on the shallow-etched region,
wherein during the second etching process, the second hard mask layer is etched first, then the first organic dielectric layer is etched, and finally the first waveguide layer is etched, and
the full-height region is located in a photolithography open area, after finishing etching the first organic dielectric layer, the first hard mask layer on the full-height region is exposed, during a process of continuing to etch the first waveguide layer, the full-height region is protected from being etched by the first hard mask layer acting as a hard mask, and the shallow-etched region is protected from being etched by a photoresist and the second hard mask layer, while a remaining region of the first waveguide layer continues to be etched downward, until an etching depth accumulates to reach a depth required by the deep-etched region before getting to a stop; and
step 4: performing a third photoetching and etching process on the first waveguide layer to complete patterning the deep-etched region of the multi-height waveguide, comprising:
forming a second organic dielectric layer on the surface of the first waveguide layer away from the substrate, while covering the full-height region and the shallow-etched region;
performing a deposition on a surface of the second organic dielectric layer and forming a third hard mask layer; and
adopting the third photoetching and etching process to pattern the first waveguide layer, and forming the deep-etched region of the multi-height waveguide,
wherein during the third etching process, the third hard mask layer is etched first, then the second organic dielectric layer is etched, and finally the first waveguide layer is etched,
the full-height region and the shallow-etched region are located in the photolithography open area; after finishing etching the second organic dielectric layer, the first hard mask layer on the full-height region and the second hard mask layer on the shallow-etched region are exposed;
during a process of continuing to etch the first waveguide layer when etching the waveguide layer, the full-height region is protected from being etched by the first hard mask layer acting as the hard mask, the shallow-etched region is protected from being etched by the second hard mask layer, and the deep-etched region is protected from being etched by the photoresist and the third hard mask layer, while a remaining region of the first waveguide layer continues to be etched downward, until the first waveguide layer is totally etched, and
the etching is adopting a hard mask self-alignment manner to etch step by step.

2. The preparation process according to claim 1, wherein the first hard mask layer is formed by a thin film deposition, and
the thin film is chosen from aluminum nitride, aluminum oxynitride, aluminum oxide, polysilicon, silicon nitride, silicon oxynitride, silicon dioxide, SiCN, or SiOCH.

3. The preparation process according to claim 1, wherein the second hard mask layer is formed by a thin film deposition, and
the thin film is chosen from aluminum nitride, aluminum oxynitride, aluminum oxide, polysilicon, silicon nitride, silicon oxynitride, silicon dioxide, SiCN, or SiOCH.

4. The preparation process according to claim 1, wherein the first organic dielectric layer is formed by coating an organic dielectric layer with a preset thickness on a surface of the full-height region and the first waveguide layer, and
the first organic dielectric layer is chosen from Amorphous Carbon, BARC, CHM701B, HM8006, HM8014, or ODL-102.

5. The preparation process according to claim 1, wherein the third hard mask layer is formed by a thin film deposition, and
the thin film is chosen from aluminum nitride, aluminum oxynitride, aluminum oxide, polysilicon, silicon nitride, silicon oxynitride, silicon dioxide, SiCN, or SiOCH.

6. The preparation process according to claim 1, wherein the etching is adopting a dry etching or a wet etching.

7. The preparation process according to claim 2, wherein the etching is adopting a dry etching or a wet etching.

8. The preparation process according to claim 3, wherein the etching is adopting a dry etching or a wet etching.

9. The preparation process according to claim 4, wherein the etching is adopting a dry etching or a wet etching.

10. The preparation process according to claim 5, wherein the etching is adopting a dry etching or a wet etching.
